(19) United States
(12) Patent Application Publication
(10) Pub. No.: US 2006/0244012 A1
(43) Pub. Date: Nov. 2, 2006

(54) Heterojunction bipolar transistor power device with efficient heat sinks

(75) Inventor: Yu-Chi Wang, Tao Yuan Shien (TW)

Correspondence Address: LOWE HAUPTMAN BERNER, LLP, 1700 DIAGONAL ROAD, SUITE 300, ALEXANDRIA, VA, 22314, US

(73) Assignee: WIN Semiconductors Corp.

(21) Appl. No.: 11/116,348

(22) Filed: Apr. 28, 2005

(51) Int. Cl. H01L 31/00

(52) U.S. Cl. 257/197

(57) ABSTRACT

A heterojunction bipolar transistor (HBT) power device with novel device layouts is disclosed. The good thermal conductivity between the ground pad and the backside metal layer make the ground pad acting as a good heat sink. The HBTs are disposed adjacent to the ground pad, so that highly uniform current and junction temperature distribution can be achieved. This arrangement prevents the device thermal runaway and make the power device to sustain higher power operations.

### BACKGROUND OF THE INVENTION

1. Field of the Invention

The present invention relates to an HBT power device with highly efficient heat sinks, and more particularly, relates to an HBT power device with a novel device layout that utilize the backside via hole as a efficient heat sink, which enables each HBT to achieve a more uniform current and junction temperature distributions and prevents the device thermal runaway under high power operations.

2. Description of the Prior Art

Power amplifiers are the most important component in various wireless communication systems. In general, a power amplifier contains many transistor units, and each unit usually consists of a number of heterojunction bipolar transistors (HBTs). For an HBT power device, there exist so-called “self-heating” problems, which would make the device thermal runway and deteriorate the device performance catastrophically. The self-heating effect originates from the positive feedback relationship between the collector current and the temperature of the transistor, which makes the transistor thermally unstable. According to the current-temperature relationship of a pn junction, higher temperature leads to an increased collector current, which in turn heats up the transistor and hence further increasing the collector current. This unstability could rapidly degrade the performance of a power transistor, or even lead to permanent damages. One approach to avoid the problem of thermal runway is to use an emitter ballasting resistor, which effectively introduces a negative feedback loop to stabilize the positive feedback system. However, when the resistance of the ballasting resistor is too large, the power gain of the HBT device will be undesirably reduced under RF operations, hence degrading the efficiency of the power amplifier.

On the other hands, thermal runaway of a HBT device could also result from a non-uniform current distribution. A HBT power transistor usually contains a plurality of emitter fingers. If the arrangement of these emitter fingers and base contacts contains some “sharp corners”, the current spreading in these emitter fingers will be highly non-uniform. This non-uniform current spreading will locally heat up the region of higher current density, then in turn further increase the current density in this region, and finally destroy the operation of the power transistor. Therefore, a suitable arrangement of emitter fingers and base contacts is also important for avoiding the non-uniform temperature distribution.

FIG. 1 illustrates a device layout of a conventional HBT power device of prior art. Each HBT generally comprises a collector region 101, a base region 102 and an emitter region 103. The collector region 101 includes a rectangular collector electrode 104 and a rectangular base region 102 (also referred as a base mesa). The base mesa includes a base electrode 105 and the emitter region 103 exterior to the base electrode 105. An emitter finger 106 is disposed on the emitter region 103, and is electrically isolated from the base region 102. A ground pad 107 is also disposed in the vicinity for grounding the emitter. For a space saving purpose, a ground pad 107 can be shared by a number of HBTs, so that the emitters of these HBTs are electrically connected to each other and to the same ground pad. FIG. 2 shows a cross-sectional view of the ground pad and structures thereunder. The ground pad 201 is electrically connected to a backside metal layer 203 through a backside via hole 202. The backside via hole can be fabricated using conventional photolithography and wet/dry etching on the wafer backside after the front metal processes. The contact between the ground pad 201 and the backside metal layer 203 also provides an efficient way for dissipating heat. Therefore, the ground pad can also be considered as a heat sink due to the good thermal contact between the emitter fingers to the backside metal layer. However, for the arrangements of emitter fingers and ground pad shown in FIG. 1, the current passing through the emitter fingers would be non-uniform, due to the different distances between emitter fingers and the grounding pad. Therefore, for achieving more uniform current distribution and providing more efficient way for heat dissipation, the arrangement of emitter fingers and the ground pad plays a crucial role.

### SUMMARY OF INVENTION

The object of the present invention is to provide a layout design of HBT power devices, which can produce highly uniform current distribution in the emitter junction and provide an efficient heat sink for dissipating heat generated during large current injection, so that the HBT can sustain higher power operations.

The feature of the device layout disclosed in the present invention is the geometric arrangement of the emitter fingers and the ground pad, by which not only the current density, but also the junction temperature are uniformly distributed.

### BRIEF DESCRIPTION OF THE DRAWING

FIG. 1 is a plan view of the layout of a conventional HBT power device of prior art,

FIG. 2 is a cross-sectional view of the via hole of prior art;

FIG. 3 is a plan view showing the device layout using the via hole as a heat sink in accordance with the first preferred embodiment of the present invention;

FIG. 4 is a plan view of the device layout using the via hole as a heat sink in accordance with the second preferred embodiment of present invention;

FIG. 5 is a plan view of the device layout with circular ground pad; and

FIG. 6 is a plan view of the device layout with hexagonal ground pad.

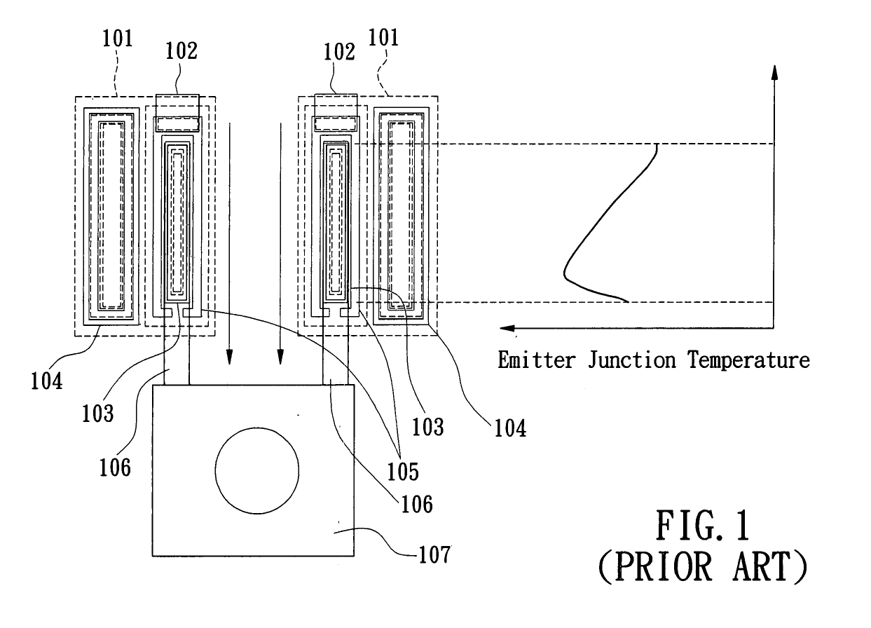

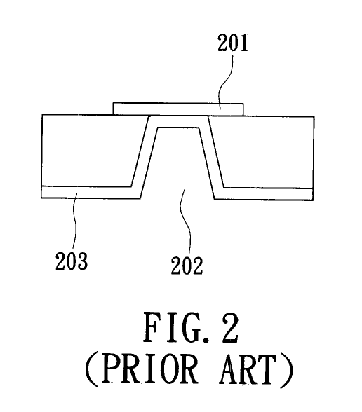

### DETAILED DESCRIPTION OF PREFERRED EMBODIMENTS

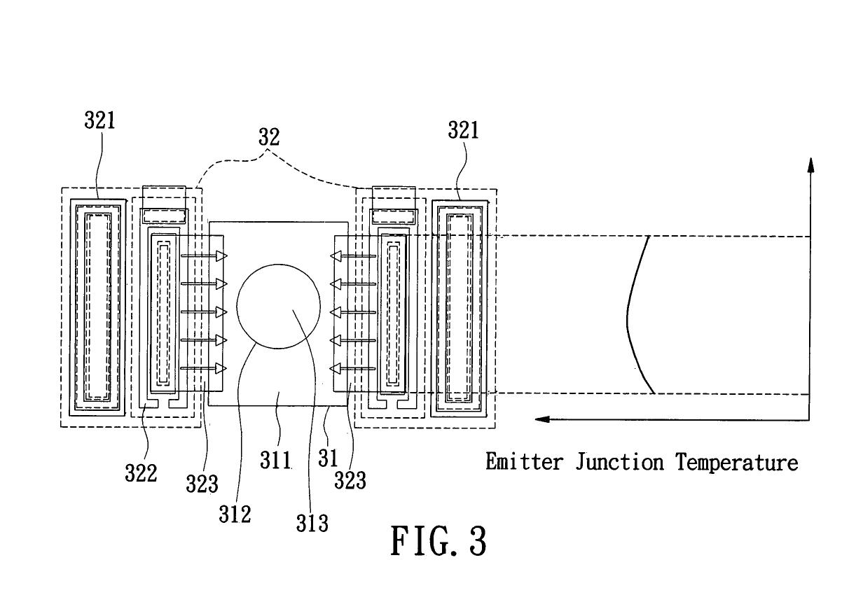

The device layouts of HBT power devices disclosed in the present invention take the advantage of the high thermal conducting feature of the ground pad and the backside metal layer connected thereto, so that the emitter fingers are disposed around the ground pad to achieve highly uniform current distribution and junction temperature. The device layout shown in FIG. 3 illustrates the main concept of the present invention, which is also the first preferred embodiment of the present invention. The feature of this layout is that the HBTs is disposed on both sides of the ground pad and adjacent to the longer side of the ground pad. Accordingly highly uniform current distribution and junction temperature can be achieved. As shown in FIG. 3, the device cell comprises a ground pad 31 of square shape and a pair of HBTs 32. The ground pad 31 not only provides grounding for the HBTs, but also acts as a high efficient heat sink, which is formed by a front metal layer 311, with a backside via hole 312 thereunder and a backside metal layer 313 being electrically contacted thereto through the via hole 312. Both the HBTs 32 include a collector electrode 321, a base electrode 322 and an emitter electrode 323. The emitter electrode 323 of each HBTs 32 has a rectangular shape, which is disposed closely on both sides of the square ground pad, whereto the emitter electrode is extended and electrically connected for grounding and dissipating heat. The feature of the device layout shown in FIG. 3 is the geometric arrangement of the pair of HBTs 32 and ground pad 31, which can obtain uniform current and temperature distributions throughout the emitter finger, so that the effect of local heating can be avoided. It is apparent that the shape of the ground pad is not limited to a square shape, which can be rectangular as well. Besides, the shape of the backside via hole is also not limited to circular. Other shapes can also provide the same function as long as the electrical and thermal contact between the ground pad and the backside metal is preserved.

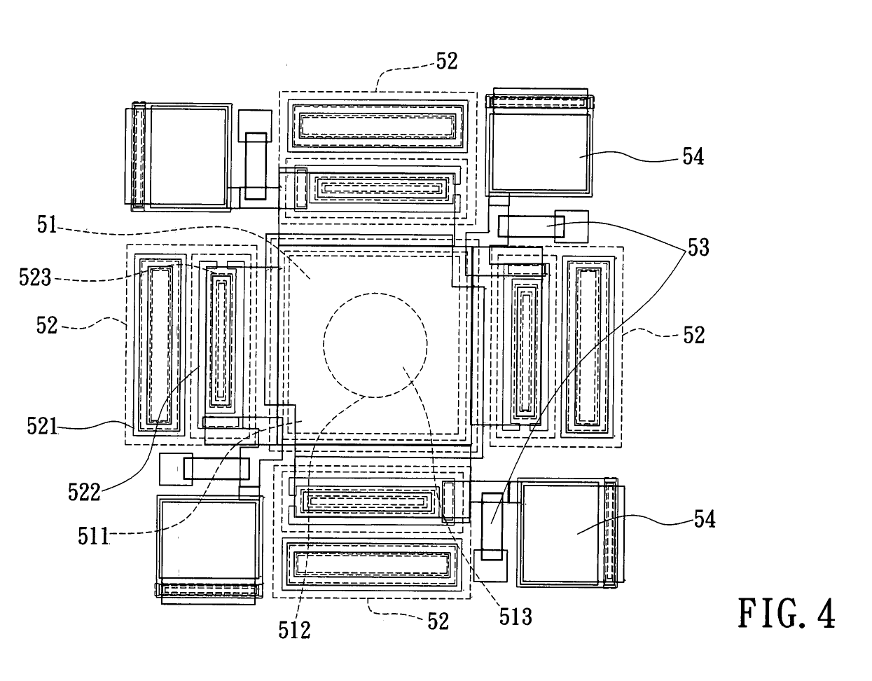

According to the concept of the first preferred embodiment, a device cell can also be designed to have four HBTs being disposed adjacent to each side of a square ground pad as shown in FIG. 4, which is also a second preferred embodiment of the present invention. The layout of the device cell comprises a square ground pad 51, four HBTs 52 and optional ballasting resistors 53 and bypass capacitors 54 if necessary. The ground pad 51 provide not only grounding for the HBTs 52, but also a efficient way for heat dissipation, which is formed by a front metal layer 511, with a backside via hole 512 thereunder and a backside metal layer 513 being electrical contacted thereto through the backside via hole 512. Each of the four HBTs includes a collector electrode 521, a base electrode 522 and an emitter electrode 523. The emitter electrode 523 can be in rectangular shape, with a longer side being parallel to one of the sides of the square ground pad 51. The emitter electrode 523 is extended to and electrical connected to the ground pad 51 to provide emitter grounding and heat dissipation. The feature of this layout is that the four HBTs 52 are at the same distance from the ground pad 51. By this arrangement, uniform current and temperature distributions can be obtained throughout the emitter finger, so that the effect of local heating can be avoided. Besides, since the four HBTs 52 are at the same distance from the ground pad 51, the degree of heat dissipation will be the same in these four HBTs, avoiding breakdown of the device cell caused by heat accumulation in one of these HBTs. It is also important to mention that we have added ballasting resistors and bypass capacitors in this embodiment. It means that this layout is not limited to elementary transistor; various components can also be incorporated to improve the HBT performance.

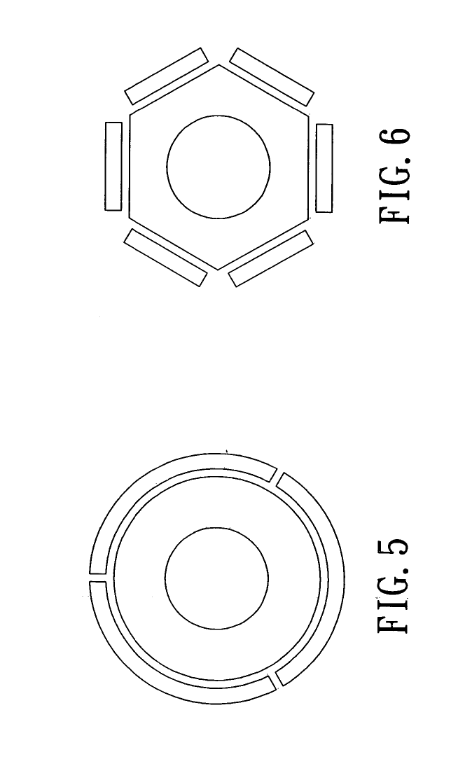

If fact, according the descriptions of the first and the second embodiments of the present invention, the shape of the ground pad is obviously not limited to square or rectangular. It can be designed to be polygonal or circular shapes, as long as the geometric arrangement between the HBTs and the ground pad lets the emitter current flow uniformly and keeps the same degree of heat dissipation among the HBTs. FIG. 5 is a plan view of the device layout with circular ground pad and FIG. 6 is a plan view of the device layout with hexagonal ground pad, which are also another two preferred embodiments of the present invention.

What is claimed is:

1. A heterojunction bipolar transistor (HBT) power device comprising a plurality of device cells, each of the device cells including
a ground pad forming by a front metal layer, with a backside via hole thereunder and a backside metal layer being electrically contacted thereto through the backside via hole; and
a plurality of HBTs, each of the HBTs being disposed in the vicinity of the ground pad, and including a collector electrode, a base electrode and a emitter electrode, the emitter electrode being extended to the ground pad for grounding and heat dissipation.

2. The HBT power device described in claim 1, wherein each device cell has a ground pad of rectangular shape and a pair of HBTs, each of the HBTs being disposed adjacent to the longer side of the rectangular ground pad.

3. The HBT power device described in claim 1, wherein each device cell has a ground pad of square shape and a total of four HBTs, each of the HBTs being disposed adjacent to each side of the square ground pad.

4. The HBT power device described in claim 1, wherein each device cell has a ground pad of N-side polygon shape and a total of N HBTs, each of the HBTs being disposed adjacent to each side of the polygonal ground pad.

5. The HBT power device described in claim 1, wherein each device cell comprise a ground pad of circular shape and a total of N HBTs, each of the HBTs being in segmental shape and disposed around the circular ground pad.

6. The HBT power device described in claim 1, wherein the shape of the backside via hole underneath the ground pad of each device cell can be circular, square, rectangular, or polygonal with arbitrary sides.
